(19) United States
(12) Patent Application Publication
(10) Pub. No.: US 2008/0253587 A1
(43) Pub. Date: Oct. 16, 2008

(54) METHOD FOR AUTOMATICALLY ADJUSTING AUDIO VOLUME AND AUDIO PLAYER

(75) Inventor: Makoto UNE, Kawasaka-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/062,906

(22) Filed: Apr. 4, 2008

(30) Foreign Application Priority Data
Apr. 11, 2007 (JP) 2007-103661

(51) Int. Cl. H03G 3/00

(52) U.S. Cl. 381/107

(57) ABSTRACT

A method is for automatically adjusting audio volume in a decoder that decodes digital audio data for each frame in which gain information that describes the audio volume of the frame is included. The method includes: storing a first gain information that is included in a preceding frame and used for decoding the preceding frame in a memory device; obtaining a second gain information that is included in a current frame; calculating a difference between the first gain information and the second gain information; adjusting the second gain information in accordance with the calculated difference; and decoding the current frame using the adjusted second gain information.

### RELATED APPLICATION(S)

The present disclosure relates to the subject matter contained in Japanese Patent Application No. 2007-103661 filed on Apr. 11, 2007, which is incorporated herein by reference in its entirety.

### FIELD

The present invention relates a method for automatically adjusting audio volume and an audio player that automatically adjusts audio volume.

### BACKGROUND

In recent years, use of audio data coded in an audio compression coding standard of high sound quality, such as AAC (Advanced Audio Coding) and MP3 (MPEG1 Audio Layer-3), has become widespread.

In data coded in AAC and MP3, a value of a global gain is described for each of frames, and an audio volume of post-decoded PCM data is determined based on the global gain value.

The decoded PCM data is reproduced in an audio player. A volume of the audio player is controlled in accordance with preferences of a user. However, in music such as classical music, the audio volume may largely fluctuate at a midpoint in a piece of music. Therefore, there occurs a case that, when the volume of the audio player is turned up in accordance with relatively small audio volume in the beginning of a piece of music, the piece of the music may be reproduced at a very large volume at a midpoint thereof.

In order to solve this problem, an automatic audio control method for automatically controlling the audio volume of PCM data has been proposed. An example of such technique is disclosed in JP-A-2000-311446.

In the conventional automatic audio control method, however, all of the PCM data need to be previously summed up to obtain an average value of the PCM data for performing the volume adjustment. Accordingly, all of the PCM data decoded from the compressed audio data needs to be previously stored in a storage device, which requires the storage device to have a large memory space.

### SUMMARY

According to a first aspect of the invention, there is provided a method for automatically adjusting audio volume in a decoder that decodes digital audio data for each frame in which gain information that describes the audio volume of the frame is included, the method including: storing a first gain information that is included in a preceding frame and used for decoding the preceding frame in a memory device; obtaining a second gain information that is included in a current frame; calculating a difference between the first gain information and the second gain information; adjusting the second gain information in accordance with the calculated difference; and decoding the current frame using the adjusted second gain information.

According to a second aspect of the invention, there is provided a method for automatically adjusting audio volume in a decoder that decodes digital audio data for each frame in which gain information that describes the audio volume of the frame is included, the method including: obtaining a volume level of an audio player that plays audio decoded by the decoder; obtaining the gain information that is included in a current frame; comparing the obtained gain information with a threshold value that is defined for the volume level; adjusting the obtained gain information in accordance with a result of the comparison; and decoding the current frame using the adjusted gain information.

According to a third aspect of the invention, there is provided an audio player including: a decoder that decodes digital audio data for each frame in which gain information that describes audio volume of the frame is included; and a memory device, wherein the decoder operates to: store a first gain information that is included in a preceding frame and used for decoding the preceding frame in the memory device; obtain a second gain information that is included in a current frame; calculate a difference between the first gain information and the second gain information; adjust the second gain information in accordance with the calculated difference; and decode the current frame using the adjusted second gain information.

### BRIEF DESCRIPTION OF THE DRAWINGS

In the accompanying drawings:

FIG. 1 is a flowchart to show a procedure example of an automatic volume adjustment method according to a first embodiment of the invention;

FIG. 2 is a drawing to show an outline of the frame configuration of audio data in AAC;

FIGS. 3A-3C are drawings to schematically show how global gains are adjusted according to the automatic volume adjustment method of the first embodiment;

FIG. 4 is a drawing to show an example of a program for calculating a scale factor based on a global gain;

FIG. 5 is a flowchart to show a procedure example of an automatic volume adjustment method according to a second embodiment of the invention;

FIGS. 6A and 6B are drawings to schematically show how scale factors are adjusted according to the automatic volume adjustment method of the second embodiment;

FIGS. 7A and 7B are drawings to schematically show how scale factors are adjusted according to the automatic volume adjustment method of the second embodiment;

FIG. 8 is a drawing to show an example of relationship between the volume level of an audio player and threshold values of a global gain;

FIG. 9 is a flowchart to show a procedure example of an automatic volume adjustment method according to a third embodiment of the invention;

FIG. 10 is a drawing to show an example of the relationship between the volume level of the audio player and the range of a adjustment global gain;

FIG. 11 is a drawing to show an example of the relationship between the volume level of the audio player and threshold values of a scale factor;

FIG. 12 is a flowchart to show a procedure example of an automatic volume adjustment method according to a fourth embodiment of the invention;

FIG. 13 is a drawing to show an example of the relationship between the volume level of an audio player and the range of a adjustment scale factor; and

FIG. 14 is a drawing to show an example of an audio player that is implemented with one of the automatic volume adjustment methods according to the first to fourth embodiments.

### DETAILED DESCRIPTION OF THE EMBODIMENT(S)

Referring now to the accompanying drawings, there are shown embodiments of the invention. In the description of the embodiments, the case where AAC is used as an audio compression coding system is taken as an example.

### First Embodiment

In a method shown as a first embodiment of the invention, a global gain is acquired from each frame of a bit stream of audio data compressed and coded in AAC, the global gain of a current frame is adjusted in response to the difference from the global gain of a preceding frame, and the adjusted global gain is used to decode compressed and coded audio data.

Therefore, when processing is performed for the global gain of the current frame following the preceding frame, difference calculation is applied to the adjusted global gain of the preceding frame. Then, to execute processing of the embodiment, the post-adjusted global gain of the preceding frame already subjected to processing is stored in memory.

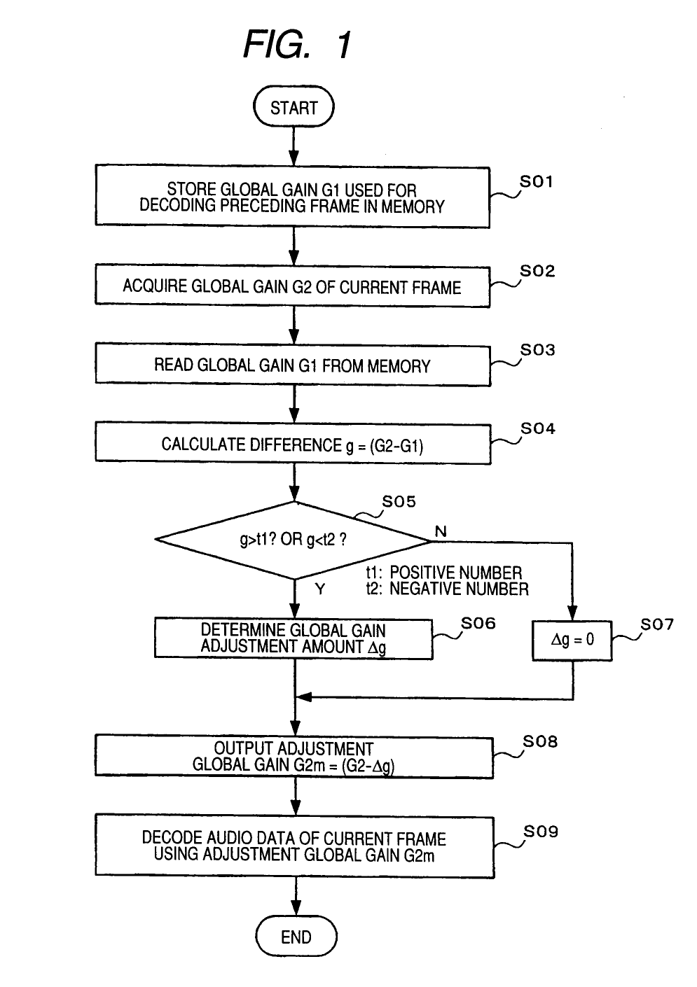

FIG. 1 is a flowchart to show a procedure example of the automatic volume adjustment method according to the first embodiment of the invention. This flow indicates the processing procedure for the current frame.

When processing of the current frame is started, first a global gain G1 used for decoding the preceding frame is stored in the memory (step S01).

Next, a global gain G2 of the current frame is acquired from a bit stream of audio data (step S02).

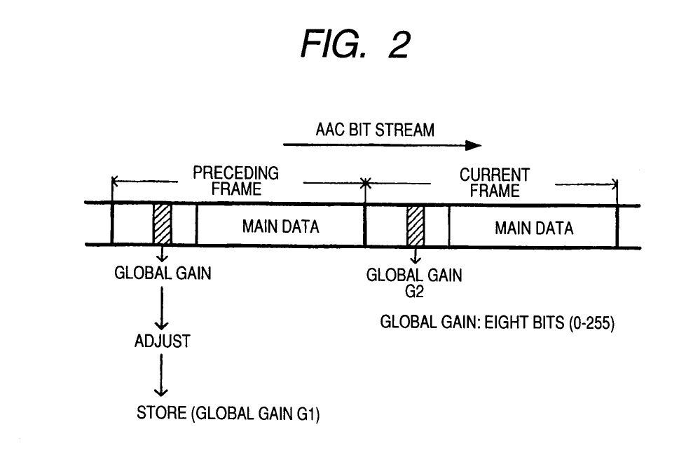

FIG. 2 shows an outline of the frame configuration of a bit stream of audio data compressed and coded in AAC.

Each frame contains not only a main data part storing the main body of audio data, but also a part describing various pieces of information concerning the main data; the global gain is described in this part as 8-bit data (in the range of 0 to 255).

The global gain of the preceding frame acquired from the bit stream is adjusted according to processing in the flow (described later) and is stored in the memory at step S01 described above as the global gain G1.

The global gain G2 of the current frame is acquired from the bit stream at step S02 described above.

Referring again to FIG. 1, then the global gain G1 is read from the memory (step S03) and a difference “g” that is a difference between the global gain G2 of the current frame and the global gain G1, namely, “g=G2−G1” is calculated (step S04).

Next, the difference g is compared with a preset threshold value and whether or not the difference g exceeds the threshold value is determined. Δs the threshold value, a positive number t1 and a negative number t2 are defined. Therefore, in the comparison, whether or not g>t1 or whether or not g<t2 is determined (step S05).

The difference g is determined to exceeds the threshold value when the global gain G2 of the current frame largely changes relative to the global gain G1 of the preceding frame. In this case, when audio data is reproduced, the audio volume largely changes. Then, when it is determined that the difference g exceeds the threshold value, the global gain G2 of the current frame is adjusted so that the global gain difference between the current and preceding frames lessens.

Thus, when it is determined that the difference g exceeds the threshold value (Y), a adjustment amount Δg to adjust the global gain G2 of the current frame is determined (step S06).

When g>t1, the adjustment amount Δg is a positive number; and when g<t2, the adjustment amount Δg is a negative number.

The adjustment amount Δg can be defined as desired. Then, for example, the adjustment amount Δg can be set to the same value as the threshold value t1, t2 and when g>t1, Δg can be set to t1; when g<t2, Δg can be set to t2.

Alternatively, the adjustment amount Δg may be the threshold value t1, t2 multiplied by a given coefficient.

On the other hand, when it is not determined that the difference g exceeds the threshold value (N), the global gain of the current frame need not be adjusted and thus the adjustment amount Δg is set to zero (step S07).

Next, the global gain of the current frame is adjusted using the adjustment amount Δg and a adjustment global gain G2m is output (step S08).

The adjustment global gain G2m is calculated by “G2m=G2−Δg”.

Next, the audio data of the current frame is decoded using the adjustment global gain G2m (step S09) and the process ends.

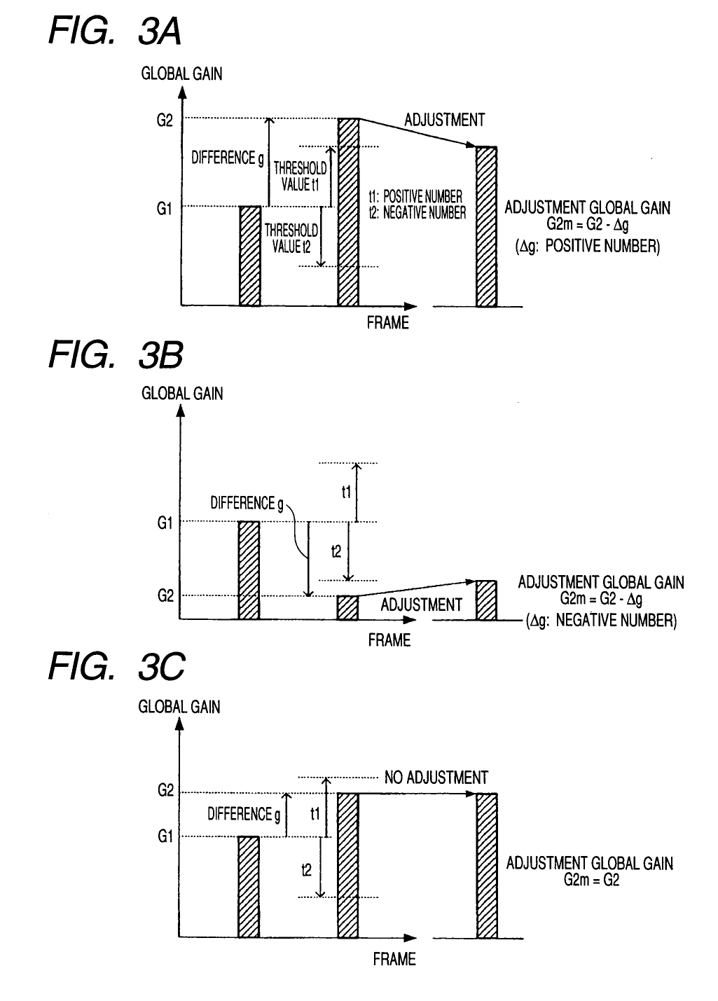

FIG. 3 schematically shows how global gains are adjusted according to the flow described above.

FIG. 3A shows an example wherein the difference g between the global gain G2 of the current frame and the global gain G1 exceeds the threshold value t1.

In the case shown in FIG. 3A, the adjustment amount Δg is determined to be a positive value and the value of the adjustment global gain G2m becomes smaller than the global gain G2. Accordingly, the global gain difference between the current and preceding frames becomes smaller than the difference before the adjustment.

FIG. 3B shows an example wherein the difference g between the global gain G2 of the current frame and the global gain G1 exceeds the threshold value t2.

In the case shown in FIG. 3B, the adjustment amount Δg is determined to be a negative value and the value of the adjustment global gain G2m becomes larger than the global gain G2. Accordingly, the global gain difference between the current and preceding frames becomes smaller than the difference before the adjustment.

FIG. 3C shows an example where the difference g between the global gain G2 of the current frame and the global gain G1 does not exceed the threshold value t1 or t2.

In the case shown in FIG. 3C, the adjustment amount Δg is determined to be zero and the value of the adjustment global gain G2m remains the same as the value of the global gain G2.

According to the embodiment, the global gain difference between the current and preceding frames is compared with the preset threshold value and when the difference exceeds the threshold value, the global gain of the current frame is adjusted so as to lessen the difference. This processing makes it possible to lessen the difference between the volume of the audio data of the current frame decoded using the adjusted global gain and the volume of the audio data of the preceding frame.

Since the global gain value range is defined to be in a range from 0 to 255 according to the standard, to make the adjustment described above, the lower and upper limit values of the adjustment global gain G2m are set to 0 and 255 respectively.

In the example, the value of the adjustment global gain G2m is retained as the value of the preceding frame immediately after the start, but may be retained in the memory as the value of the current frame for the next frame immediately after the adjustment global gain G2m is calculated.

In the above description, the term “current frame” and the term “preceding frame” are used. The preceding frame may be a frame immediately before the current frame or may be any one or more frames preceding the current frame. The adjustment of the global gain may be performed by using an average global gains of a plurality of preceding frames that precede the current frame. Alternatively, the global gain of the n-th frame (globalGain (n)) may be obtained in consideration of an accumulation from a first frame as such by using the following equation:

globalGain(n)=globalGain(n−1)+g*0.5

### Second Embodiment

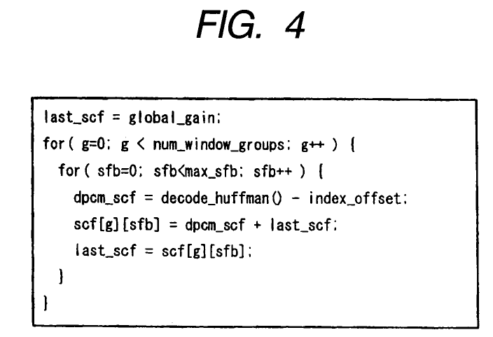

The value of the global gain described in each frame is used as the initial value when the scale factor for each frequency band of the frame is calculated. FIG. 4 shows an example of a program for calculating the scale factor based on the global gain. The program is executed, thereby calculating a scale factor scf[ ] for each of the frequency bands partitioned according to an index (sfb).

Accordingly, a second embodiment of the invention is shown as an example of a method of calculating the scale factor difference between the current and preceding frames, adjusting the scale factor of the current frame in response to the difference, and decoding compressed and coded audio data using the adjusted scale factor.

In the second embodiment, when processing for the scale factor of the current frame following the preceding frame is performed, difference calculation is applied to the adjusted scale factor of the preceding frame. Then, to execute processing according to the second embodiment, the post-adjusted scale factor of the preceding frame already subjected to processing is stored in a memory.

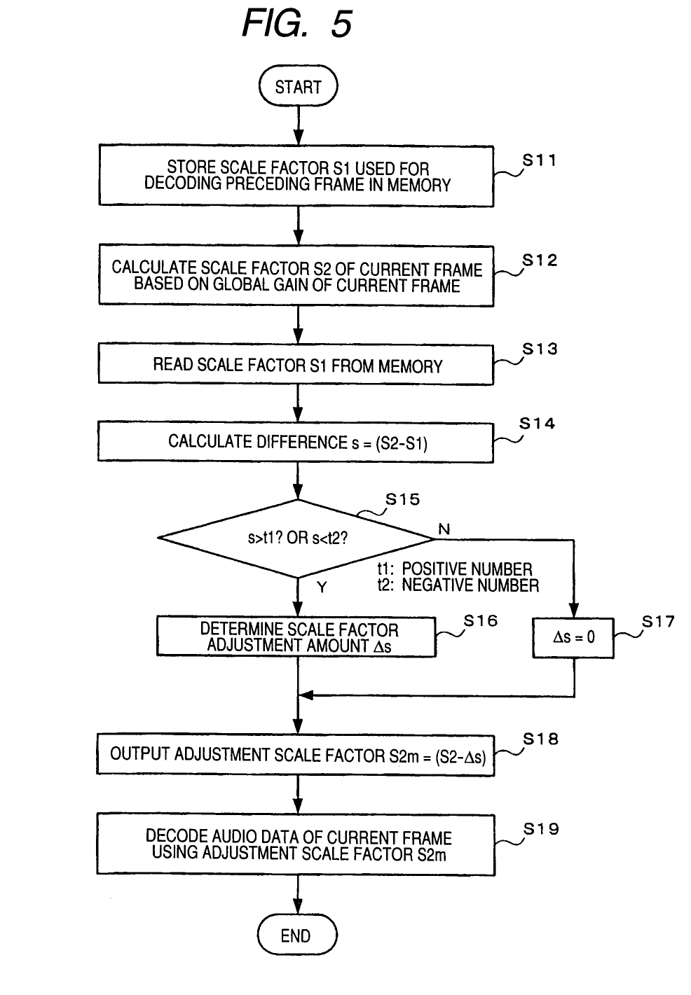

FIG. 5 is a flowchart to show a procedure example of the automatic volume adjustment method according to the second embodiment of the invention. The flow shown in FIG. 5 is an example of the processing procedure for the current frame.

When processing of the current frame is started, a scale factor S1 used for decoding the preceding frame is stored in the memory (step S11).

Next, a global gain of the current frame is acquired from a bit stream of audio data and a scale factor S2 of the current frame is calculated based on the global gain (step S12).

Next, the scale factor S1 is read from the memory (step S13) and a difference “s” that is a difference between the scale factor S2 of the current frame and the scale factor S1, namely, “s=S2−S1” is calculated (step S14).

Next, the difference s is compared with a preset threshold value and whether or not the difference s exceeds the threshold value is determined. Δs the threshold value, a positive number t1 and a negative number t2 are defined. Therefore, in the comparison, whether or not s>t1 or whether or not s<t2 is determined (step S15).

The difference s is determined to exceed the threshold value when the scale factor S2 of the current frame largely changes relative to the scale factor S1 of the preceding frame. In this case, when audio data is reproduced, the audio volume largely changes. Accordingly, when it is determined that the difference s exceeds the threshold value, the scale factor S2 of the current frame is adjusted so that the scale factor difference between the current and preceding frames lessens.

Thus, when it is determined that the difference s exceeds the threshold value (Y), a adjustment amount Δs to adjust the scale factor S2 of the current frame is determined (step S16).

When s>t1, the adjustment amount Δs is a positive number; and when s<t2, the adjustment amount Δs is a negative number.

The adjustment amount Δs can be defined as desired. Then, for example, the adjustment amount Δs can be set to the same value as the threshold value t1, t2 and when s>t1, Δs can be set to t1; when s<t2, Δs can be set to t2.

Alternatively, the adjustment amount Δs may be the threshold value t1, t2 multiplied by a given coefficient.

On the other hand, when it is not determined that the difference s exceeds the threshold value (N), the scale factor of the current frame need not be adjusted and thus the adjustment amount Δs is set to zero (step S17).

Next, the scale factor of the current frame is adjusted using the adjustment amount Δs and a adjustment scale factor S2m is output (step S18).

The adjustment scale factor S2m is calculated by “S2m S2−Δs”.

Next, the audio data of the current frame is decoded using the adjustment scale factor S2m (step S19) and the processing flow is terminated.

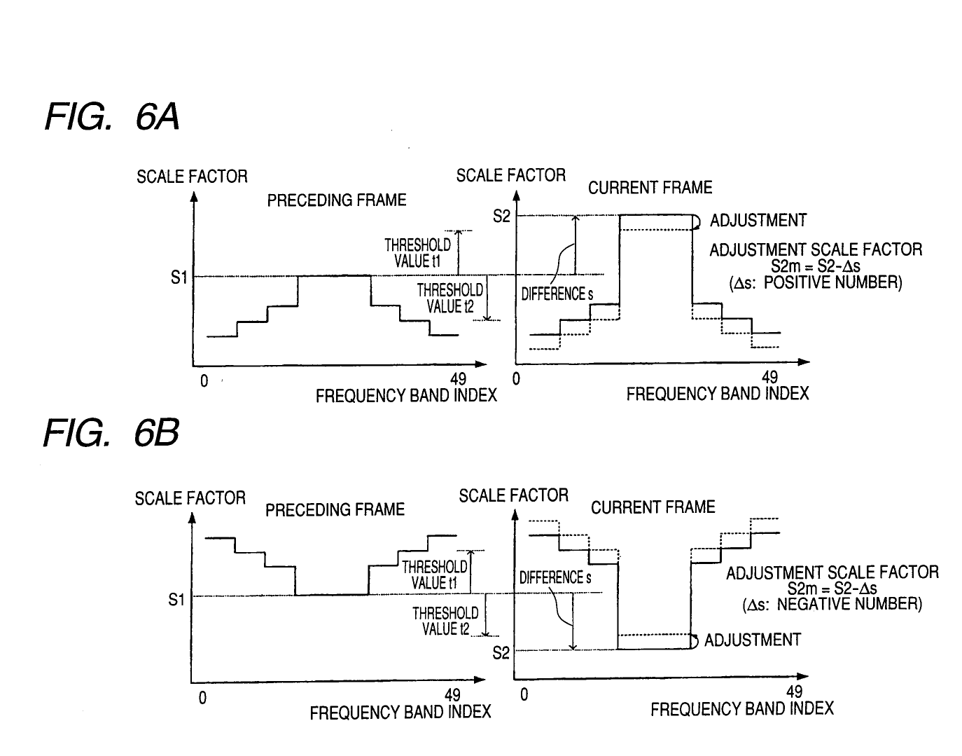

FIGS. 6A and 6B schematically show how scale factors are adjusted according to the flow described above.

FIG. 6A shows an example wherein the difference s between the scale factor S2 of the frequency band of one index of the current frame and the scale factor S1 of the same frequency band of the preceding frame exceeds the threshold value t1.

In the case shown in FIG. 6A, the adjustment amount Δs is determined a positive value. In the example, the scale factors of all frequency bands are adjusted uniformly based on the adjustment amount Δs. Consequently, the value of the adjustment scale factor S2m after the adjustment becomes smaller than the scale factor S2. Accordingly, the scale factor difference between the current and preceding frames becomes smaller than the difference before the adjustment.

FIG. 6B shows an example wherein the difference s between the scale factor S2 of the current frame and the scale factor S1 exceeds the threshold value t2.

In the case shown in FIG. 6B, the adjustment amount Δs is determined a negative value and the scale factors of all frequency bands are adjusted uniformly based on the adjustment amount Δs. Consequently, the value of the adjustment scale factor S2m after the adjustment becomes larger than the scale factor S2. Accordingly, the scale factor difference between the current and preceding frames also becomes smaller than the difference before the adjustment.

Since the scale factor value range is defined to be in a range from 0 to 256 according to the standard, to make the adjustment described above, the lower and upper limit values of the adjustment scale factor S2m are set to 0 and 256 respectively.

In the example shown in FIG. 6, the scale factors of all frequency bands are adjusted uniformly. However, the scale factor may be adjusted only for the frequency band with the difference s from the scale factor of the preceding frame exceeding the threshold value.

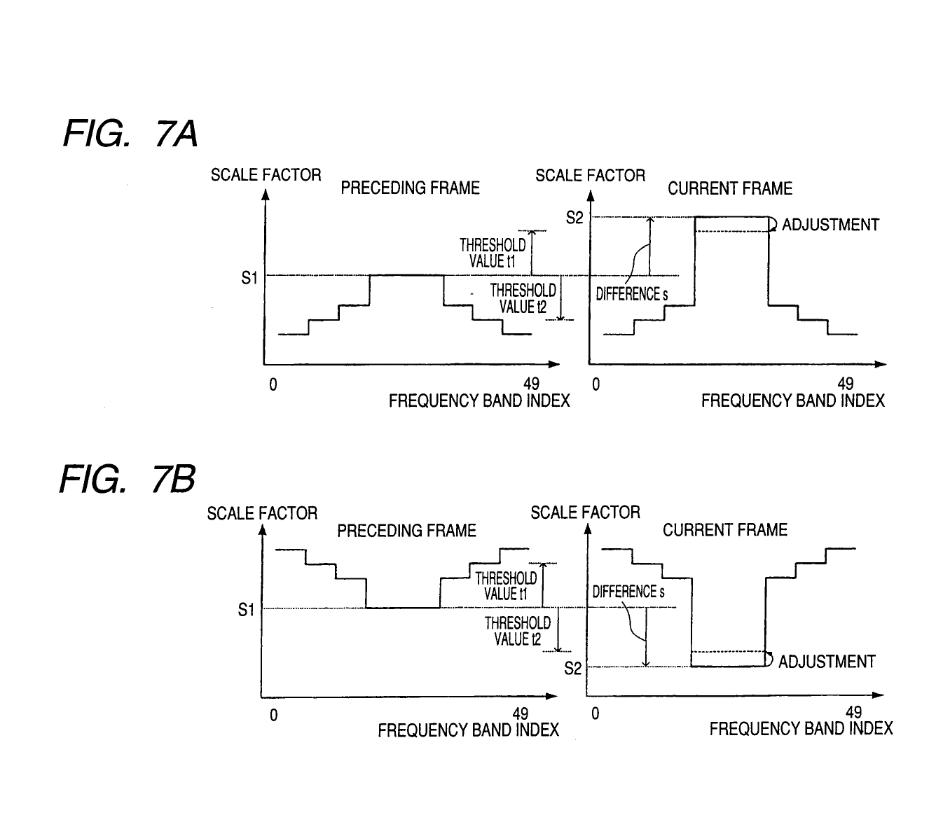

FIGS. 7A and 7B schematically show an example of adjusting the scale factor only for the frequency band with the difference s exceeding the threshold value.

FIG. 7A shows an example wherein the difference s between the scale factor S2 of the frequency band of one index of the current frame and the scale factor S1 of the same frequency band of the preceding frame exceeds the threshold value t1.

In the case shown in FIG. 7A, the adjustment amount Δs is determined a positive value and only the scale factor of the frequency band exceeding the threshold value t1 is adjusted based on the adjustment amount Δs. Consequently, the value of the adjustment scale factor S2m after the adjustment becomes smaller than the scale factor S2. Accordingly, the scale factor difference between the current and preceding frames in the frequency band becomes smaller than the difference before the adjustment.

FIG. 7B shows an example wherein the difference s between the scale factor S2 of the current frame and the scale factor S1 exceeds the threshold value t2.

In the case shown in FIG. 7B, the adjustment amount Δs is determined a negative value and only the scale factor of the frequency band exceeding the threshold value t1 is adjusted based on the adjustment amount Δs. Consequently, the value of the adjustment scale factor S2m after the adjustment becomes larger than the scale factor S2. Accordingly, the scale factor difference between the current and preceding frames in the frequency band also becomes smaller than the difference before the adjustment.

According to the second embodiment, it is possible to adjust the scale factor for each frequency band, so that it is possible to control the audio volume for each frequency band.

In the example, the value of the adjustment scale factor S2m is retained as the value of the preceding frame immediately after the start, but may be retained in the memory as the value of the current frame for the next frame immediately after the adjustment scale factor S2m is calculated.

### Third Embodiment

In the first embodiment, the difference of the global gain of the current frame from that of the preceding frame is calculated. Thus, the global gain of the preceding frame needs to be stored in the memory. In a third embodiment of the invention, a method of controlling the audio volume using only the global gain of the current frame is shown.

In the third embodiment, the global gain is adjusted in response to a volume level of an audio player that plays the audio data. That is, if the volume of the audio player is set so that the volume becomes large, when a large global gain value is described, the global gain is adjusted so as to become smaller than the value; whereas, if the volume of the audio player is set so that the volume becomes small, when a small global gain value is described, the global gain is adjusted so as to become larger than the value.

Thus, in the third embodiment, a threshold value t3 indicating the maximum value of the global gain and a threshold value t4 indicating the minimum value are preset for each volume level of an audio player.

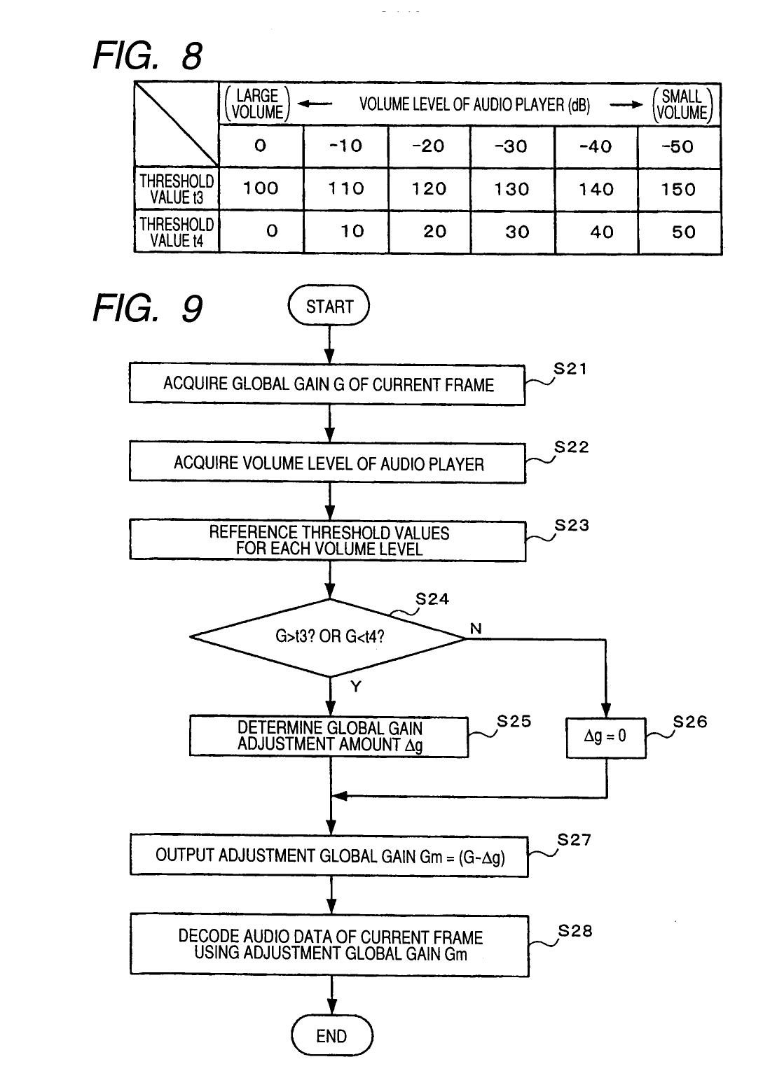

FIG. 8 shows a setting example of the threshold values t3 and t4 of the global gain for the volume level of an audio player.

The specifications of the volume of an audio player vary from one audio player to another; here, it is assumed that an attenuation amount of 0 dB to −50 dB can be set. 0 dB means that no attenuation of the audio volume exists; the larger the minus value, the smaller becomes the volume.

If the threshold values are set as shown in FIG. 8, for example, when the value of the global gain is 140, if the volume level of the audio player is 0 dB, the value exceeds the threshold value t3; if the volume level of the audio player is −50 dB, the value does not exceed the threshold value t3. When the value of the global gain is 40, if the volume level of the audio player is −50 dB, the value exceeds the threshold value t4; if the volume level of the audio player is 0 dB, the value does not exceed the threshold value t4.

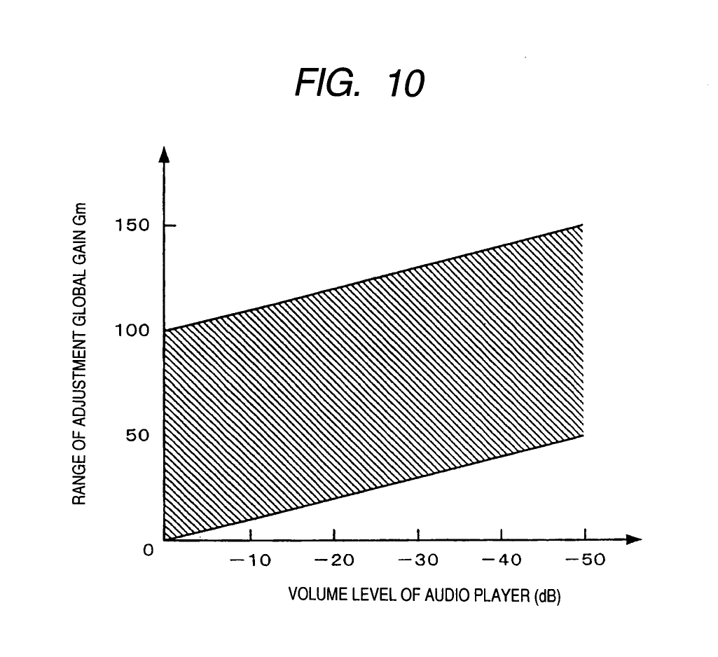

FIG. 9 is a flowchart to show a procedure example of the automatic volume adjustment method of the third embodiment of the invention.

When processing of the current frame is started, first a global gain G of the current frame is acquired from a bit stream of audio data (step S21).

Next, the volume level of the audio player is acquired through command processing, etc., from outside a decoder (step S22).

Next, a threshold value table for the volume levels (FIG. 8) is referenced and the threshold values t3 and t4 corresponding to the acquired volume level are determined (step S23).

Next, the global gain G is compared with the threshold values t3 and t4 to determine whether or not the global gain G exceeds the threshold value t3 or t4. That is, whether or not G>t3 or whether or not G<t4 is determined (step S24).

Thus, when it is determined that the global gain G exceeds the threshold value t3 or t4 (Y), a adjustment amount Δg to adjust the global gain G is determined (step S25).

When G>t3, the adjustment amount Δg is set to “Δg=G−t3”; and when C<t4, the adjustment amount Δg is set to “Δg=G−t4”.

On the other hand, when it is not determined that the global gain G exceeds the threshold value (N), the global gain of the current frame need not be adjusted and thus the adjustment amount Δg is set to zero (step S26).

Next, the global gain G is adjusted using the adjustment amount Δg to output a adjustment global gain Gm (step S27).

The adjustment global gain Gm is calculated by “Gm=G−Δg”.

Such a adjustment is made, whereby the adjustment global gain Gm falls within the range of the threshold values t3 and t4. However, since the global gain value range is defined as 0 to 255 according to the standard, to make the adjustment described above, the lower and upper limit values of the adjustment global gain Gm are set to 0 and 255 respectively as in the first embodiment.

Next, the audio data of the current frame is decoded using the adjustment global gain Gm (step S28) and the processing flow is terminated.

FIG. 10 shows the relationship between the range of the adjustment global gain calculated according to the flow described above and the volume level of the audio player.

As shown in FIG. 10, the global gain value is adjusted so as to shift in a direction in which the whole range of the global gain becomes larger as the volume level of the audio player is smaller.

According to the third embodiment, the global gain of the current frame is adjusted in sequence in response to the volume level of the audio player, so that the decoded audio data is reproduced at a proper volume level regardless of the magnitude of the volume level of the audio player. Accordingly, manual volume control during the playback can be lessened and the convenience of the user can be improved.

### Fourth Embodiment

In a fourth embodiment of the invention, a method of controlling the audio volume based on the global gain acquired from the current frame is also shown as in the third embodiment. Shown in the fourth embodiment is a method of controlling the volume by adjusting the scale factor calculated based on the global gain in response to the volume level of an audio player of audio data.

In the fourth embodiment, if the volume of the audio player is set so that the volume becomes large, when a scale factor of a large value is calculated, the scale factor is adjusted so as to become smaller than the value; whereas, if the volume of the audio player is set so that the volume becomes small, when a scale factor of a small value is described, the scale factor is adjusted so as to become larger than the value.

Thus, in the fourth embodiment, a threshold value t3 indicating the maximum value of the scale factor for each frequency band and a threshold value t4 indicating the minimum value are preset for each volume level of an audio player.

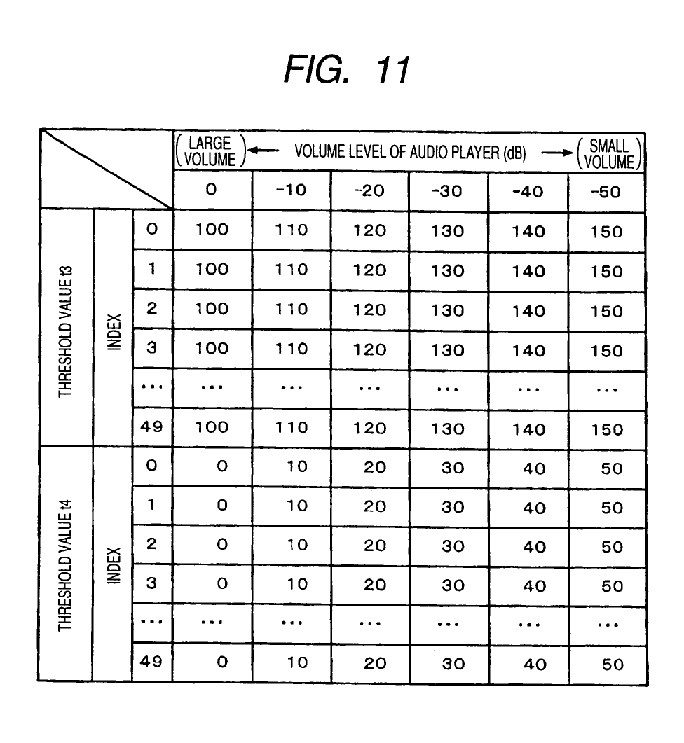

FIG. 11 shows a setting example of the threshold values t3 and t4 of the scale factor for the volume level of an audio player.

In the example, for the same volume level, the threshold value for each frequency band distinguished according to an index is the same, but a different threshold value may be set according to the frequency band.

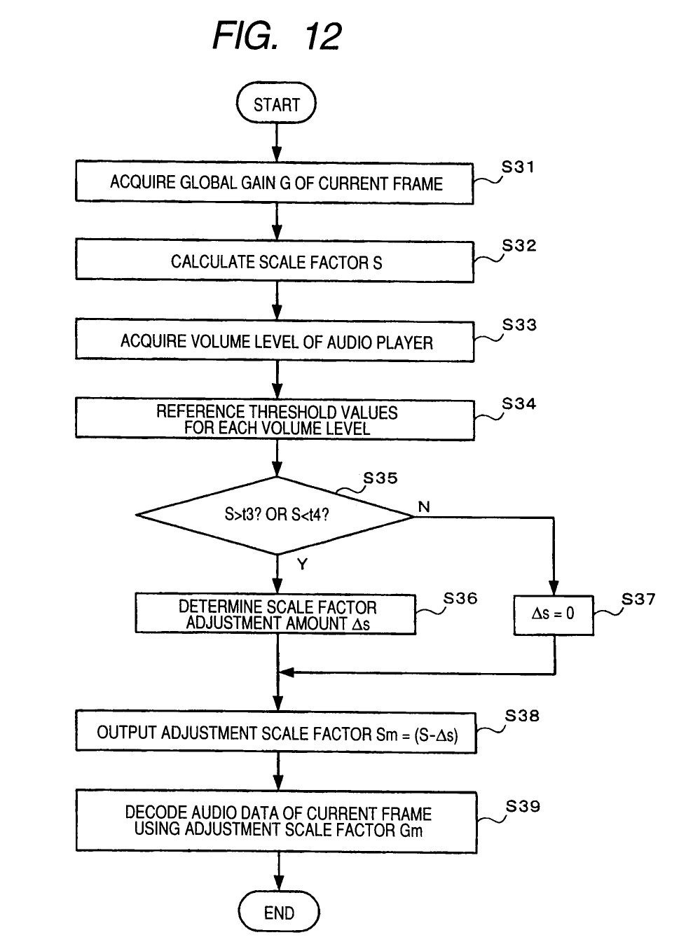

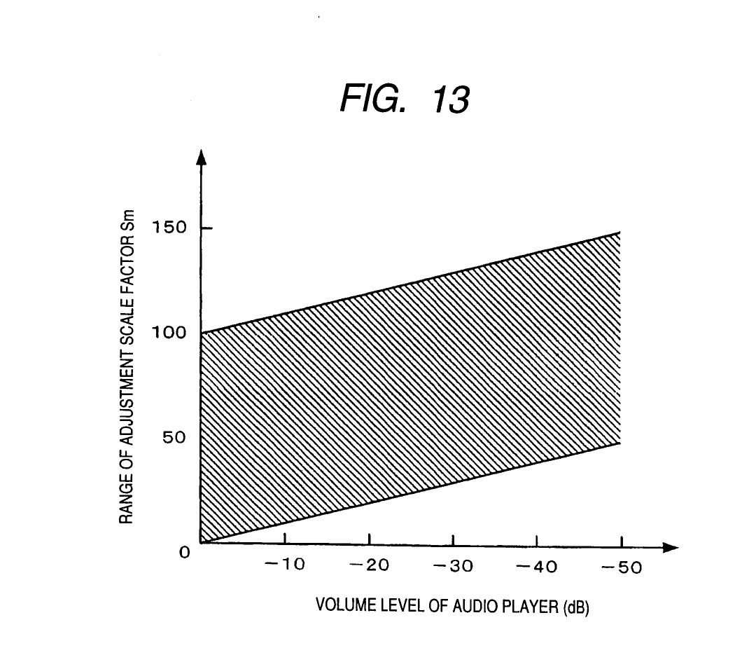

FIG. 12 is a flowchart to show a procedure example of the automatic volume adjustment method of the fourth embodiment of the invention.

When processing of the current frame is started, first the global gain of the current frame is acquired from a bit stream of audio data (step S31) and a scale factor S is calculated based on the global gain (step S32).

Next, the volume level of the audio player is acquired through command processing, etc., from outside a decoder (step S33).

Next, a threshold value table for the volume levels (FIG. 11) is referenced and the threshold values t3 and t4 corresponding to the acquired volume level are determined (step S34).

Next, the scale factor S is compared with the threshold values t3 and t4 to determine whether or not the scale factor S exceeds the threshold value t3 or t4. That is, whether or not S>t3 or whether or not S<t4 is determined (step S35).

Thus, when it is determined that the scale factor S exceeds the threshold value t3 or t4 (Y), a adjustment amount Δs to adjust the scale factor S is determined (step S36).

When S>t3, the adjustment amount Δs is set to “Δs=S−t3”; and when S<t4, the adjustment amount Δs is set to “Δs=S−t4”.

On the other hand, when it is not determined that the scale factor S exceeds the threshold value (N), the scale factor of the current frame need not be adjusted and thus the adjustment amount Δs is set to zero (step S37).

Next, the scale factor S is adjusted using the adjustment amount Δs and a adjustment scale factor Sm is output (step S38).

The adjustment scale factor Sm is calculated by “Sm=S−Δs”.

Such a adjustment is made, whereby the adjustment scale factor Sm falls within the range of the threshold values t3 and t4. However, since the scale factor is defined to be in a range from 0 to 256 according to the standard, to make the adjustment described above, the lower and upper limit values of the adjustment scale factor Sm are set to 0 and 256 respectively as in the second embodiment.

Next, the audio data of the current frame is decoded using the adjustment scale factor Sm (step S39) and the processing flow is terminated.

FIG. 13 shows the relationship between the range of the adjustment scale factor calculated according to the flow described above and the volume level of the audio player.

As shown in FIG. 13, the scale factor value is adjusted so as to shift in a direction in which the whole range of the scale factor becomes larger as the volume level of the audio player is smaller.

According to the fourth embodiment, the scale factor of the current frame is adjusted in sequence in response to the volume level of the audio player, so that the decoded audio data is reproduced at a proper volume level regardless of the magnitude of the volume level of the audio player. At this time, if a different threshold value is set for each frequency band, different volume control can be executed for each frequency band.

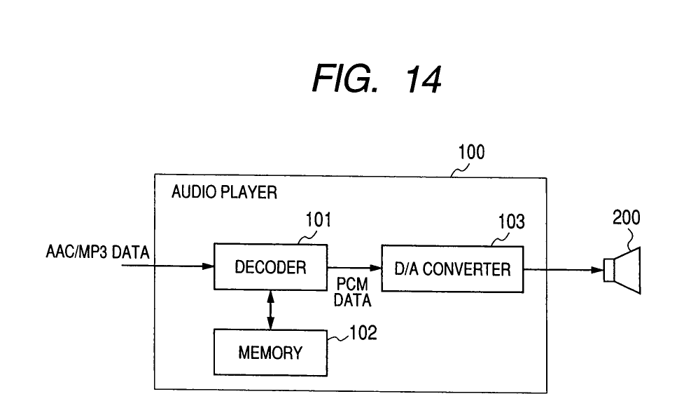

The automatic volume adjustment methods according to the first to fourth embodiments as described above may be implemented in an audio player 100 as shown in FIG. 14. The audio player 100 is provided with a decoder 101, a memory 102, and a D/A converter 103.

The decoder 101 decodes an AAC data or an MP3 data input therein by performing a process according to one of the automatic volume adjustment methods as described as the first to fourth embodiments and outputs a PCM data to the D/A converter 103.

The memory 102 is connected to the decoder 101 and used as a buffer or a temporary storage for storing the global gain or the scale factor. The memory 102 may also store a software program that causes the decoder to operate for performing one of the automatic volume adjustment methods, or may also store tables as shown in FIGS. 8 and 11. The memory 102 may be configured to be built in the decoder 101.

The D/A converter 103 converts the digital PCM data into analogue audio signal, and outputs the audio signal to a speaker 200. The D/A converter 103 may be configured to be built in the decoder 101.

The audio player 100 may include a processor that is provided separately from the decoder 101, and configured that the processor performs at least a part of the decoding process including processes for performing the automatic volume adjustment methods as described in the first to fourth embodiments.

What is claimed is:

1. A method for automatically adjusting audio volume in a decoder that decodes digital audio data for each frame in which gain information that describes the audio volume of the frame is included, the method comprising:
storing a first gain information that is included in a preceding frame and used for decoding the preceding frame in a memory device;
obtaining a second gain information that is included in a current frame;
calculating a difference between the first gain information and the second gain information;
adjusting the second gain information in accordance with the calculated difference; and
decoding the current frame using the adjusted second gain information.

2. The method according to claim 1, wherein a first global gain that is included in the preceding frame and used for decoding the preceding frame is stored in the memory device as the first gain information,
wherein a second global gain that is included in the current frame is obtained as the second gain information,
wherein a difference between the first global gain and the second global gain is calculated,
wherein the second global gain is adjusted to fit in a predetermined range when the calculated difference exceeds a threshold value, and
wherein the current frame is decoded using the adjusted second global gain.

3. The method according to claim 1, wherein first scale factors that are obtained based on a global gain that is included in the preceding frame and used for decoding the preceding frame is stored in the memory device as the first gain information,
wherein second scale factors for each frequency band are obtained as the second gain information based on a global gain that is included in the current frame,
wherein differences between the first scale factors and the second scale factors are calculated for each frequency band,
wherein the second scale factors are adjusted to fit in a predetermined range when the calculated differences exceeds a threshold value, and
wherein the current frame is decoded using the adjusted second scale factors.

4. The method according to claim 3, wherein the adjustment of the second scale factors is only performed for the second scale factor having the difference that exceeds the threshold value.

5. A method for automatically adjusting audio volume in a decoder that decodes digital audio data for each frame in which gain information that describes the audio volume of the frame is included, the method comprising:
obtaining a volume level of an audio player that plays audio decoded by the decoder;
obtaining the gain information that is included in a current frame;
comparing the obtained gain information with a threshold value that is defined for the volume level;
adjusting the obtained gain information in accordance with a result of the comparison; and
decoding the current frame using the adjusted gain information.

6. The method according claim 5, wherein a global gain that is included in the current frame is obtained as the gain information,
wherein the obtained global gain is compared with the threshold value,
wherein the obtained global gain is adjusted to fit in a predetermined range when the global gain exceeds the threshold value, and
wherein the current frame is decoded using the adjusted global gain.

7. The method according to claim 5, wherein scale factors for each frequency band, which are obtained based on a global gain that is included in the current frame, are obtained as the gain information,
wherein the obtained scale factors are compared with threshold values that are defined for each frequency band and for the volume level,
wherein the obtained scale factors are adjusted to fit in a predetermined range when the scale factors exceed the threshold values, and
wherein the current frame is decoded using the adjusted scale factors.

8. The method according to claim 7, wherein the adjustment of the scale factors is only performed for the scale factor that exceeds the respective threshold value for the frequency band of the scale factor.

9. An audio player comprising:
a decoder that decodes digital audio data for each frame in which gain information that describes audio volume of the frame is included; and
a memory device,
wherein the decoder operates to:
store a first gain information that is included in a preceding frame and used for decoding the preceding frame in the memory device;
obtain a second gain information that is included in a current frame;
calculate a difference between the first gain information and the second gain information;
adjust the second gain information in accordance with the calculated difference; and
decode the current frame using the adjusted second gain information.
